(19) United States
(12) Patent Application Publication
(10) Pub. No.: US 2007/0056504 A1
(43) Pub. Date: Mar. 15, 2007

(54) Method and apparatus to produce single crystal ingot of uniform axial resistivity

(75) Inventor: John C. Lim, Lake Arrowhead, CA (US)

Correspondence Address: MORGAN LEWIS & BOCKIUS LLP, 1111 PENNSYLVANIA AVENUE NW, WASHINGTON, DC, 20004, US

(73) Assignee: REXOR CORPORATION

(21) Appl. No.: 11/222,841

(22) Filed: Sep. 12, 2005

(51) Int. Cl. C30B 15/00; C30B 21/06; C30B 27/02; C30B 28/10; C30B 30/04

(52) U.S. Cl. 117/13

(57) ABSTRACT

A method for producing a single crystal ingot includes steps of providing a first amount of polycrystalline material and a first amount of dopant material to form a first mixture having a first dopant concentration in a process furnace, increasing a temperature of the first mixture to provide a molten first mixture, providing a seed material to the molten first mixture, withdrawing the seed from the molten first mixture by a first distance to form a boule having a first length, providing a second amount of the polycrystalline material and a second amount of the dopant material to the molten first mixture to provide a molten second mixture having the first dopant concentration, withdrawing the first length of the boule from the molten second mixture by a second distance to form the boule having a second length, and removing the boule from the molten second mixture to form the single crystal ingot of uniform axial resistivity.

### BACKGROUND OF THE INVENTION

1. Field of Invention

The present invention relates to a method and apparatus for producing single crystal material and, in particular, to a method and apparatus for producing single crystal ingot of uniform axial resistivity.

2. Discussion of the Related Art

Single crystal silicon, Group IV element, is the basic substance used for virtually all semiconductor devices. Other single crystal materials which are also finding applications in semiconductor devices are Periodic Table Group III elements, particularly in combination with Group V elements, e.g., germanium and gallium arsenide. These materials are synthetically produced in a purified and perfect, single crystal form. The method traditionally used for such production has been the Czochralski method. In the Czochralski method, polycrystalline material, such as hyper-pure germanium or silicon, is melted and maintained in a molten state in a quartz crucible. The quartz crucible is mounted within a heated furnace, usually supported by a graphite cup. A seed crystal of silicon is dipped in the molten silicon and is slowly withdrawn, forming a cylindrical boule of single crystal silicon. The boule and crucible are rotated counter-rotationally to promote uniformity of silicon properties and distribution of impurities and dopant additives within the silicon.

The Czochralski process is conducted batch-wise and inherent limitations of batch-wise processing cause, or promote, variations in properties and composition of the resulting silicon boule. Dopants such as phosphorus or boron are usually added to the silicon melt to impart desirable semiconductor properties to the silicon wafers which are sliced from the cylindrical silicon boule. The dopants, due to its selective segregation property, tend to concentrate in the molten pool as the pool is depleted by the forming of the boule.

These disadvantages of the Czochralski process have led to the improved processes which are described in U.S. Pat. Nos. 4,659,421, 5,314,667, and 5,580,171, the entirety of which are hereby incorporated by reference. In these improved processes, a shallow molten pool of silicon is maintained in a crucible to reduce the variation of dopant distribution and the reduction in the oxygen contents in the cylindrical boule withdrawn from the pool. Polycrystalline silicon is continuously introduced into a silicon replenishment zone which is separated from the crystal growth zone, where the boule is formed. In the U.S. Pat. Nos. 5,314,667 and 5,580,171, the replenishment zone is an annular zone surrounding the central crystal-growth zone.

Silicon is continuously introduced into the furnaces of these improved processes. In U.S. Pat. No. 4,659,421, the polycrystalline silicon rod is not only continuously fed into the molten silicon pool but also to stir the melt, while in U.S. Pat. Nos. 5,314,667 and 5,580,171, granular silicon is introduced into the replenishment zone.

It is also difficult to introduce a granular material into a high temperature furnace at closely controlled feed rates, as required to avoid upsetting the process conditions within the furnace. A common problem with all silicon crystal growth furnaces is the impossibility of obtaining a uniform distribution of the minor quantities of dopant throughout the polycrystalline silicon supplied to the furnace so that variations in dopant concentration are avoided in the melt and subsequently in the single crystal boule.

During production of the single-crystal boule, only a fraction of the dopant in the molten pool of silicon is incorporated into the boule. For example, using boron as the dopant materials, only 80% of the boron is picked up by the boule from the molten pool of silicon. Accordingly, the remaining 20% of the boron accumulates in the molten pool of silicon for the next phase of crystallization. This results in incorporation of more dopant in the next crystallization phase, thereby increasing the dopant content in the crystal, thus, reducing the resistivity of the boule. As a result, when the silicon ingot (i.e., finished boule) is sliced into individual semiconductor wafers, resistivity values of a first-sliced semiconductor wafer will vary continually as compared to a last-sliced semiconductor wafer. Thus, the resistivity values of the first-sliced semiconductor wafers are not the same as the later-sliced semiconductor wafers.

The resistivity of the silicon ingot is inversely related to the dopant concentration in the silicon material. In addition, the dopant uptake (i.e., segregation coefficient) into the silicon boule is uniquely characteristic of the dopant species in the silicon melt. In the case of boron, the segregation coefficient is 0.80 and about 80% of the boron within the molten pool of silicon is incorporated into the boule. In the case of phosphorous, the segregation coefficient is 0.35 and about 35% of the phosphorous within the molten pool of silicon is incorporated into the silicon boule. For arsenic, the segregation coefficient is 0.30. As a result, a residual fraction of about 20% for boron, about 65% for phosphorous, and about 70% for arsenic continuously accumulates in the molten pool of silicon.

FIG. 1 is an elevation view of a Czochralski process furnace according to the prior art. In FIG. 1, the furnace 10 is contained in a surrounding vacuum chamber 12 formed from an upper half shell 14 and a lower half shell 16 which are joined together by annular flanges 18. The upper half shell 14 has a viewing port 20 and a centrally located, axially extending crystal receiving chamber 22. The vacuum chamber 12 contains a centrally located, furnace 10 which includes a circular heater 24 formed of vertical graphite elements 26 which are supplied with electrical power from electrical leads 31 which pass into the chamber through connectors 29. The heater 24 is surrounded by a protective cylindrical heat shield 28.

A centrally located shaft 30 extends axially into the lower shell 16, and this shaft is mounted for rotational and axial movement. The upper end 32 of the shaft 30 supports a graphite cup 34 in which is placed a quartz crucible 36. The crucible 36 has a generally conical bottom and has tall, vertical sidewalls to contain a sufficient quantity of molten silicon 33 from which the silicon boule is pulled.

A substantial quantity of feed material such as polycrystalline silicon is placed in the crucible and is heated to its melt temperature, in excess of 1400 centigrade, and is maintained as a molten pool, 33, by the furnace 10. In addition, while added at the time of the polycrystalline charge before heating, a specific quantity of dopant material is added while the polycrystalline materials is charged. A single seed crystal of silicon is dipped into the molten pool 33 and is slowly withdrawn, while being rotated in a counter-rotational direction to the rotation of the graphite cup-and crucible. As the crystal is withdrawn, the molten silicon at the crystal solid/liquid interface crystallizes, along with dopant, forming a cylindrical boule 35.

In FIG. 1, as the molten pool 33 is diminished by the formation of the up-taking single crystal silicon boule, the crucible is raised in the furnace to maintain the liquid level. The vacuum chamber continuously is swept with a flow of argon which is introduced through the crystal receiving chamber 22 and which flows along the upper shell 14, downwardly about the cylindrical silicon boule 35 and across the molten pool 33 of the silicon. This flow of argon sweeps silicon oxide, which is formed by reaction of the silicon melt with the quartz crucible, from the vacuum chamber 12. The next subsequent melt process will begin with 120% of the dopant species, in case of boron, within the molten pool 33, thereby producing a single crystal ingot having a non-uniform, decreasing axial resistivity.

FIG. 2 is an elevation view of another Czochralski process furnace according to the prior art. In FIG. 2, a circular baffle 38 is centrally positioned in the crucible 37, closely surrounding the cylindrical boule 35 dividing a shallow molten pool 48 into a crystal growth zone 40 and an annular feed zone 42 entirely surrounding crystal growth zone 40. Crucible 37 is received within a graphite cup 39 which is surrounded by heater 24 and by a bottom heater 54. Electrical power is supplied to heater 54 by another power supply plate 56.

The polycrystalline silicon in granular form, typically with an average particle diameter from 1 to about 1.5 millimeters, continuously is introduced into the annular zone, thus establishing this zone, not only as an annular feed zone but also as a melting zone. For this purpose, a solids hopper 44 can be located on the upper half shell 14, and a feed conduit 46 is passed through the upper half shell 14 and terminates immediately above the surface of the shallow molten pool 48. Feed conduit 46 is positioned adjacent the inside vertical wall of crucible 37, to introduce the feed material at a location closely adjacent to the inside vertical wall of crucible 37. The polycrystalline material is supplied to hopper 44 in granular or powered form and dopant material such as elemental phosphorus, elemental boron, etc. in elemental or alloy form, can also be introduced in the proportions required or desired in the single crystal silicon produced by the process.

This process starts with a shallow melt. The shallow molten pool, 48, within the crucible is maintained at a very shallow depth, from about 1.5 inches to no greater than about 2.0 inches, preferably from about 1.25 inches to about 1.75 inches, by limiting the amount of polycrystalline silicon initially introduced and thereafter by equalizing the level of the melt by the rate of replenishment of silicon, as controlled by the rate of withdrawal of the cylindrical boule 35, with the rate of introduction of the feed material to crucible 37. In a typical application, boule 35 is withdrawn at a rate from about 30 to about 60 millimeters per hour.

Cylindrical boule 35 of single crystal silicon is withdrawn from crucible 37 and passes through a heated zone 52 entirely surrounded by cylindrical heater 24. This heated zone 52 serves as an annealing zone in which the crystal is annealed to prevent thermal shocking which cracks boule 35.

As current integrated circuit technologies increase and continual progress is made in the nanotechnology and solar cell fields, production of improved semiconductor wafers are required having uniform resistivities. Improved methods and apparatus are required in order to produce single crystal ingots having uniform axial resistivities.

### SUMMARY OF THE INVENTION

Accordingly, the present invention is directed to a method and apparatus for producing single crystal ingot of uniform resistivity (i.e., axial resistivity) from the top to the tail of the boule that substantially obviate one or more of problems due to limitations and disadvantages of the related art.

The present invention is also directed to a method of producing a single crystal ingot having a uniform axial resistivity.

The present invention is also directed to an apparatus for producing a single crystal ingot having a uniform axial resistivity.

Additional features and advantages of the invention will be set forth in the description which follows, and in part will be apparent from the description, or may be learned by practice of the invention. In certain embodiments, the features and advantages of the invention will be realized and attained by the structure particularly pointed out in the written description and claims hereof as well as the appended drawings.

To achieve these and other advantages and in accordance with the purpose of the present invention, as embodied and broadly described, a method for producing a single crystal ingot includes steps of providing a first amount of polycrystalline material and a first amount of dopant material to form a first mixture having a first dopant concentration in a process furnace, increasing a temperature of the first mixture to provide a molten first mixture providing a seed material to the molten first mixture, withdrawing the seed from the molten first mixture by a first distance to form a boule having a first length, providing a second amount of the polycrystalline material and a second amount of the dopant material to the molten first mixture to provide a molten second mixture having the first dopant concentration, withdrawing the first length of the boule from the molten second mixture by a second distance to form the boule having a second length, and removing the boule from the molten second mixture to form the single crystal ingot.

In another aspect, an apparatus to produce a single crystal ingot having uniform resistivity (i.e., axial resistivity) includes a processing chamber, a processing furnace within the processing chamber, a crucible disposed within the processing furnace, the crucible containing a first amount of molten silicon and dopant materials having a first dopant concentration, a system for inserting and withdrawing a crystal seed into and from the melt. In addition, an apparatus includes a first feed system for supplying a second amount of polycrystalline material to the first amount of molten silicon and dopant materials to produce a second amount of molten silicon and dopant materials in the crucible, a second feed system for supplying a second amount of dopant material to the second amount of molten silicon and dopant materials in the crucible to produce a third amount of molten silicon and dopant materials having the first dopant concentration. Moreover, an apparatus includes a system for dipping a crystal seed into the first amount of molten silicon and dopant materials having the first dopant concentration to produce a boule having a first length, and for withdrawing the boule from the third amount of molten silicon and dopant materials having the first dopant concentration to produce the boule having a second length.

In another aspect, a crystal ingot includes a first end and a second end, wherein the crystal ingot has a generally constant resistivity (i.e., axial resistivity) along its length from the first end to the second end.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is an elevation view of a Czochralski process furnace according to the prior art;

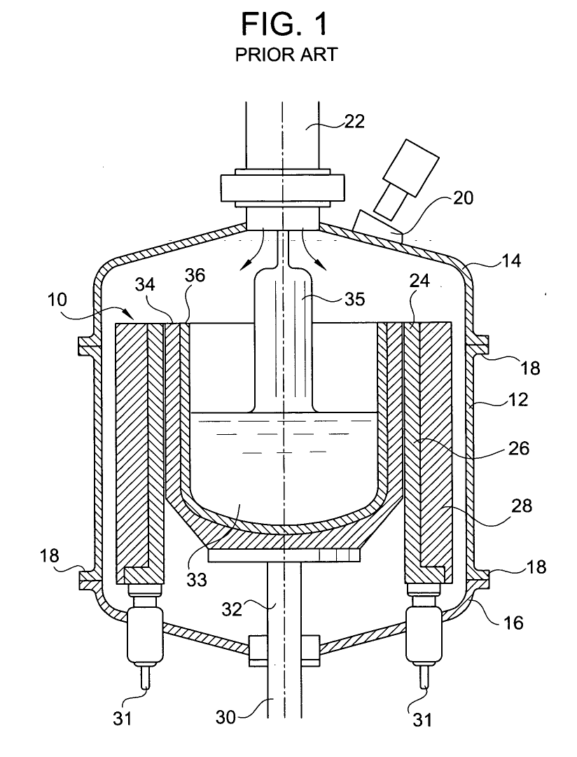

FIG. 2 is an elevation view of another Czochralski process furnace according to the prior art;

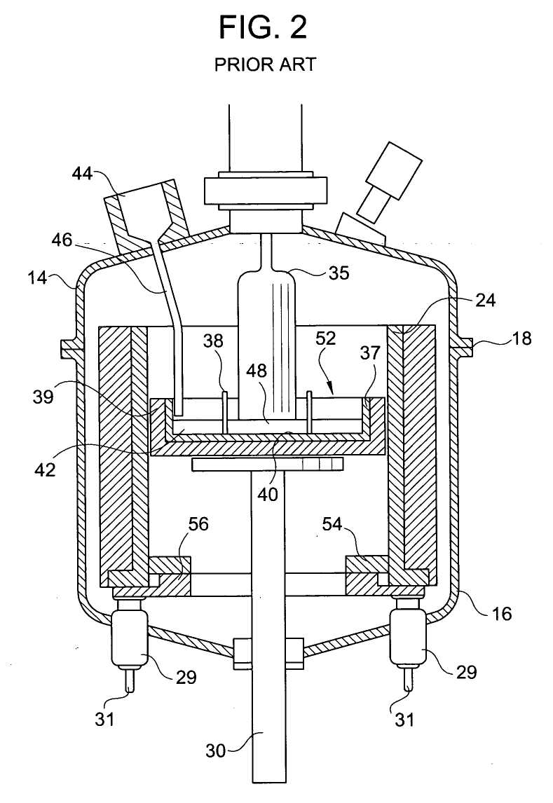

FIG. 3 is an elevation view of an exemplary modified Czochralski process furnace according to the present invention;

FIG. 4 is an elevational view, partially in cross section of the vertical transfer tubes according to the present invention; and

FIG. 5 is a block diagram of an exemplary method of producing a single crystal ingot according to the present invention.

### DETAILED DESCRIPTION OF THE PREFERRED EMBODIMENTS

Reference will now be made in detail to the embodiments of the present invention, examples of which are illustrated in the accompanying drawings.

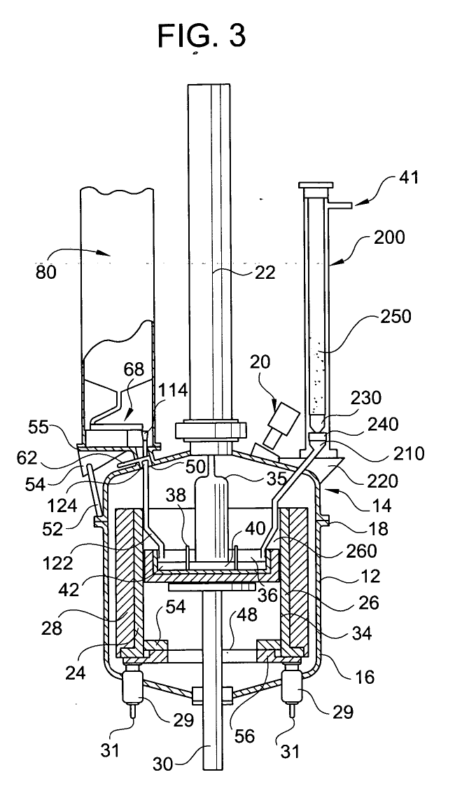

FIG. 3 is an elevation view of an exemplary modified Czochralski process furnace of one embodiment according to the present invention. In FIG. 3, a furnace 10 is contained within a surrounding vacuum chamber 12 formed from an upper half shell 14 and a lower half shell 16 which are joined together by annular flanges 18. Upper half shell 14 has a viewing port 20 and a centrally located, axially extending crystal receiving chamber 22. Vacuum chamber 12 contains a centrally located, furnace 10 which includes a circular heater 24 formed of vertical graphite elements which are supplied with electrical power from electrical leads 31 which pass into the chamber through connectors 29. Heater 24 is surrounded by a protective cylindrical heat shield 28.

A centrally located shaft 30 extends axially into the lower shell 16, and this shaft is mounted for rotational and axial movement. An upper end 32 of shaft 30 supports a graphite cup 34 in which is placed a quartz crucible 36. Crucible 36 has a flat bottom, and short side walls, thereby minimizing the quantity of the molten pool of silicon.

A circular baffle 38 is centrally positioned in crucible 36, closely surrounding cylindrical boule 35 dividing shallow molten pool 48 into a crystal growth zone 40 and an entirely surrounding annular feed zone 42. Crucible 36 is received within a graphite cup 34 which is surrounded by heater 24 and by a bottom heater 54, wherein electrical power is supplied to bottom heater 54 by plate 56.

In one embodiment, a single seed crystal of silicon is dipped into shallow molten pool 48 in the crystal growth zone 40 and is slowly withdrawn, while being rotated in a counter-rotational direction to the rotation of the graphite cup 34 and crucible 36. As a crystal is withdrawn, the molten silicon at the crystal solid/liquid interface crystallizes, forming a cylindrical boule 35.

A vacuum chamber is continuously swept with a flow of argon which is introduced through the crystal receiving chamber 22 and which flows along upper shell 14, downwardly about cylindrical silicon boule 35 and across shallow molten pool 48 of the silicon. Accordingly, the flow of argon sweeps silicon oxide, which is formed by reaction of the silicon melt with quartz crucible 36, from the vacuum chamber 12.

In FIG. 3, a solid feed system may be housed in vessel 80 which is supported on furnace 10, secured to nozzle 50 of upper shell 14, and supported by an arm 52 which is attached to a support bracket 54 on the lower end plate 56 of the vessel 40. Vessel 80 is supported beside crystal receiving chamber 22 and has a nozzle 60 in its lower end plate 56 which is bolted to a flanged nozzle 50 of an upper portion of the furnace 10. A slide gate valve 62 is placed between furnace 10 and vessel 80, thereby permitting isolation of the vessel 80 from the furnace 10. In addition, a static solids mixer 64 may be located along an upper portion of vessel 80, a solids storage hopper 66 may be located along a mid-section of vessel 80, and a solids flow controller 68 may be located along a lower portion of vessel 80.

In FIG. 3, a dopant alloy conveyor system may be housed in vessel 200 which is supported on the furnace 10, secured to nozzle feedthrough 210 of upper shell 14, and supported by a support bracket 220 which is attached to upper shell 14. Vessel 200 is supported beside crystal receiving chamber 22 and has a valve/nozzle 230 disposed above a load reading device (i.e., load cell) 240, all of which is disposed within a bottom region of vessel 200. Accordingly, nozzle feedthrough 210 is disposed immediately beneath load reading device 240 to receive dopant alloy material 250 via the valve/nozzle 230. A measured amount of the dopant alloy material 250 is transferred to the annular feed zone 42 of the molten pool 48 of silicon via a vertical transfer tube 260 leading from the bottom region of the vessel 200.

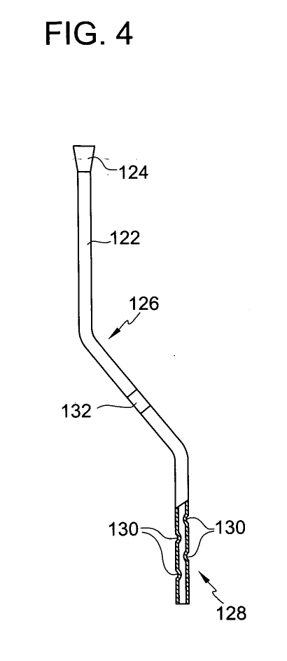

FIG. 4 is an elevational view, partially in cross section of one embodiment of vertical transfer tubes according to the present invention. In FIG. 4, both of the vertical transfer tubes 122 and 260 may have a radiation interrupt section 126, and a flow velocity control section 128. The velocity flow control section 128 may have a plurality of internal constrictions, which may be formed by indentations 130 in the side walls of tubes 122 and 260, with adjacent internal constrictions (corresponding to indentations 130) being located on opposite sides of tube 122 and 260. Accordingly, constrictions assist in deflecting solids passing through in the tubes 122 and 260, interrupting their free fall into the molten pool 48 of silicon, and prevent splashing of molten silicon within annular feed zone 42.

The polycrystalline material, such as silicon in granular form, typically with an average particle diameter from 1 to about 1.5 millimeters, is introduced into an upper end of the vessel 14, where it cascades downwardly. In one embodiment, the storage hopper has a capacity from 100 to about 240 kilograms of granular solids, sufficient for storage of the feed material required for one to four runs, making silicon ingots of about 50 kilograms.

Cylindrical boule 35 of single crystal silicon is withdrawn from crucible 36 and passes through a heated zone entirely surrounded by the cylindrical heater 24. This heated zone serves as an annealing zone in which the crystal is annealed and conditioned to obtain maximum crystal properties.

In one embodiment, the present invention is practiced and adopted to use an existing Czochralski furnace and vacuum chamber with minor but significant modifications. This resulted in substantial savings in equipment and time, as the existing Czochralski equipment was adaptable to practice the method.

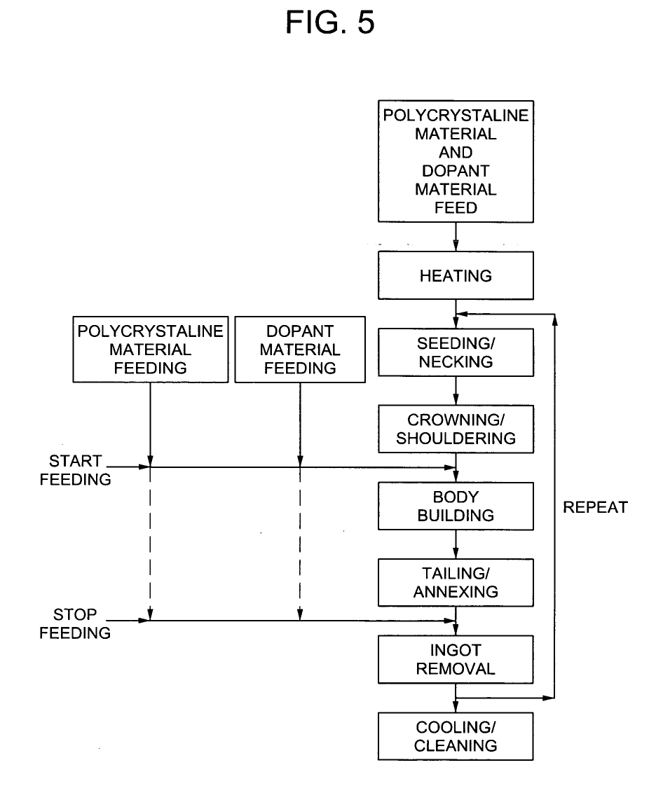

FIG. 5 is a block diagram of an exemplary method of producing a single crystal ingot according to one embodiment of the present invention. In FIG. 5, a polycrystalline material, such as granular silicon, is provided to a crucible 37 (in FIG. 3) disposed within a process furnace 14 (in FIG. 3). Then, the dopant material, such as granular solids, are added together to crucible 37 (in FIG. 3). Next, the polycrystalline and dopant materials are heated in crucible 37 (in FIG. 3) by elevating the process furnace temperature.

After the polycrystalline and dopant materials have melted and stabilized to a specific temperature, for example, of 1405 to 1415 degrees centigrade within the crucible, a single crystal seed is dipped into the melt. Next, the seed and crucible are rotated along opposing directions, and the crystal is seeded. Then, the seeded crystal is slowly withdrawn from the melt and an initial portion of the single crystal boule (i.e., neck portion) is formed. During withdrawal of the neck portion, both a crown and shoulder are formed. Next, additional amounts of polycrystalline and dopant materials are independently added to the crucible. Specifically, the amounts of the polycrystalline and dopant materials are added to crucible in order to maintain about 2.0 inches of silicon melt in the crucible, and maintain enough of the dopant material in the silicon melt to provide an ingot having a resistivity of about 20.00 ohmcm. However, the amounts of the polycrystalline and dopant materials added to crucible are necessary to maintain enough of the dopant material in the silicon melt to provide an ingot having a specific resistivity. Accordingly, the amounts of the polycrystalline and dopant materials added to crucible are necessary to produce an ingot having uniform resistivity (i.e., uniform axial resistivity).

Furthermore, the amount of the dopant material may be varied depending upon the desired dopant species being used. For example, since boron and phosphorous have different segregation coefficients, then the amounts of either the boron dopant materials or the phosphorous dopant materials may be varied, but not in a same batch. Accordingly, the dopant level in the melt remains constant.

For example, in one embodiment, initially about a 2.0 inch depth of polycrystalline material is placed in the crucible along with a calculated amount of the dopant material in order to produce a p-type single crystal ingot of specific resistivity of about 20.00 ohmcm, which may result in a dopant concentration of about 8.0×10¹⁴ atoms/cm³. Of course, the amount of dopant material will be determined by the desired resistivity of the single crystal ingot.

Next, after the additional polycrystalline and dopant materials have been added, the seeded crystal is pulled further from the melt, thereby forming a body portion of the boule. Formation of the body portion of the boule includes continued withdrawal from the melt in order to form a single crystal ingot. In addition, in one embodiment, the body portion of the boule is subjected to an annealing process to normalize crystal properties of the single crystal ingot.

Next, after the boule has been withdrawn from the melt by a specific amount (usually corresponding to a final length of the boule), the boule is pulled rapidly from the melt to form a conical tail portion. Then, the finished boule ingot is annealed, removed from the process furnace.

During the process, as shown in FIG. 5, the polycrystalline material feeding and dopant material feeding may continue during the steps of body building and tailing/annexing, but may be stopped after the step of tailing/annexing. In addition, after the step of ingot removal, the process of forming the boule is repeated in order to produce another ingot having uniform axial resistivity. This process may continue in order to repeatedly produce ingots having uniform axial resistivity.

According to the present invention, a single crystal ingot may be formed having a uniform axial resistivity by independently replenishing both polycrystalline silicon and dopant materials in a process chamber. In addition, replenishment of the polycrystalline (i.e., the rate of the polycrystalline silicon replenishment in conjunction with the crystal growth) and dopant materials may be varied in order to maintain a specific dopant concentration within the silicon melt.

It will be apparent to those skilled in the art that various modifications and variations can be made in the method and apparatus for producing single crystal ingot of uniform axial resistivity without departing from the spirit or scope of the invention. Thus, it is intended that the present invention cover the modifications and variations of this invention provided they come within the scope of the appended claims and their equivalents.

1. A method for producing a single crystal ingot, comprising steps of:
providing a first amount of polycrystalline material and a first amount of dopant material to form a first mixture having a first dopant concentration in a process furnace;
increasing a temperature of the first mixture to provide a molten first mixture;
providing a seed material to the molten first mixture;
withdrawing the seed from the molten first mixture by a first distance to form a boule having a first length;
providing a second amount of the polycrystalline material and a second amount of the dopant material to the molten first mixture to provide a molten second mixture having the first dopant concentration;
withdrawing the first length of the boule from the molten second mixture by a second distance to form the boule having a second length; and
removing the boule from the molten second mixture to form the single crystal ingot having a uniform axial resistivity.

2. The method according to claim 1, wherein a resistivity of the boule along the first and second lengths is constant.

3. The method according to claim 2, wherein the single crystal ingot has n-type impurities.

4. The method according to claim 2, wherein the single crystal ingot has p-type impurities.

5. The method according to claim 1, wherein the step of providing the second amount of the polycrystalline material is performed independently of the step of providing the second amount of the dopant material.

6. The method according to claim 1, wherein the step of providing the second amount of the polycrystalline material and the second amount of the dopant material to the molten first mixture is performed after forming the boule having the first length and before forming the boule having the second length.

7. An apparatus to produce a single crystal ingot having uniform axial resistivity, comprising:
a processing chamber;
a processing furnace within the processing chamber;
a crucible disposed within the processing furnace, the crucible containing a first amount of molten silicon and dopant materials having a first dopant concentration;
a first feed system for supplying a second amount of polycrystalline material to the first amount of molten silicon and dopant materials to produce a second amount of molten silicon and dopant materials in the crucible;
a second feed system for supplying a second amount of dopant material to the second amount of molten silicon and dopant materials in the crucible to produce a third amount of molten silicon and dopant materials having the first dopant concentration; and
a system for dipping a crystal seed into the first amount of molten silicon and dopant materials having the first dopant concentration to produce a boule having a first length, and for withdrawing the boule from the third amount of molten silicon and dopant materials having the first dopant concentration to produce the boule having a second length.

8. The apparatus according to claim 7, wherein the first and second feed systems are provided to pass through the processing chamber into the processing furnace.

9. The apparatus according to claim 8, wherein the first and second feed systems are provided along opposing sides of the processing chamber.

10. A crystal ingot having a first end and a second end, wherein the crystal ingot has a generally constant axial resistivity along its length from the first end to the second end.

11. The crystal ingot according to claim 10, wherein the axial resistivity is within a range of about 20.39 ohm-cm to about 20.21 ohm-cm.
